(19) United States
(12) Patent Application Publication
(10) Pub. No.: US 2012/0151747 A1
(43) Pub. Date: Jun. 21, 2012

(54) PROCESS FOR PRODUCING OF A THERMOELECTRIC GENERATOR APPLICABLE IN AN EXHAUST LINE OF A MOTOR VEHICLE

(75) Inventors: Thorsten ANDRES, Paderborn (DE); Sven PRZYBYLSKI, Paderborn (DE); Tobias DUEPMEIER, Paderborn (DE)

(73) Assignee: BENTELER AUTOMOBIL TECHNIK GMBH, Pederborn (DE)

(21) Appl. No.: 13/324,388

(22) Filed: Dec. 13, 2011

(30) Foreign Application Priority Data
Dec. 15, 2010 (DE) 102010061247.2

(51) Int. Cl. H05K 13/00

(52) U.S. Cl. 29/592.1

(57) ABSTRACT

A method for producing a thermoelectric generator configured to be used in an exhaust system of a motor vehicle. The thermoelectric generator includes a plurality of tubular thermoelectric modules arranged in a housing and including external pipes, internal pipes, p-doped and n-doped thermoelectric elements, and external rings. The thermoelectric modules are separated from one another on a face side by pipe bottoms. The method steps include connecting, by a gas-tight connection, the external pipes with the housing and the pipe bottoms; applying an electrically insulating coating onto inside surface of the external pipes; sliding the internal pipes including the p-doped and n-doped thermoelectric elements, and the external rings into the external pipes; shrinking the external pipes and fitting the external pipes into the internal pipes.

This application claims benefit of and priority to German Patent Application No. 10 2010 061 247.2-33, filed Dec. 15, 2010, the content of which Application is incorporated by reference herein.

### BACKGROUND AND SUMMARY

The present disclosure relates to a method for producing a thermoelectric generator that can be used in an exhaust system of a motor vehicle.

In the design of energy-efficient motor vehicle concepts, thermoelectric generators (TEG) are gaining increasing importance in power generation in the exhaust system of motor vehicles.

For example, DE 10 2006 039 024 A1 describes thermoelectric generators which are arranged as ring elements and which circumferentially enclose the discharge pipe of an exhaust system. Several thermoelements are arranged behind one another in the axial direction of the discharge pipe. In the case of a respective dimensioning of the thermoelectric generators, several of the thermal electric generators described in the above specification can be combined in a pipe bundle, as is described, for example, in DE 10 2006 019 282 A1. A pipe bundle for energy recovery in the exhaust-gas recirculation consisting of thermoelectric generators is used in this specification.

In the production of such thermoelectric generators, especially in the bundling of such TEG pipes into a pipe bundle, it is always necessary to take into account the maximally permissible process temperatures for the thermoelectric materials. The maximally permissible process temperature is limited, on the one hand, by the melt temperature of the employed solders for electric and thermal contact of the thermoelectric materials and, on the other hand, by the temperature resistance of the thermoelectric materials themselves. As a result of their temperature sensitivity, the thermoelectric modules, as described above, cannot be processed with conventional thermal processes such as vacuum soldering by nickel-base solders. That is why the sequence of the individual method steps for producing respective thermoelectric generators must be adapted to the aforementioned boundary conditions.

The present disclosure further relates to a method for producing a thermoelectric generator that can be used in an exhaust system of a motor vehicle. Such thermoelectric generators include several tubular thermoelectric modules that can be produced in a simple way.

Thus, the present disclosure relates to a method for producing a thermoelectric generator configured to be used in an exhaust system of a motor vehicle. The thermoelectric generator includes a plurality of tubular thermoelectric modules arranged in a housing and includes external pipes, internal pipes, p-doped and n-doped thermoelectric elements, and external rings. The thermoelectric modules are separated from one another on a face side by pipe bottoms. The method steps include: connecting, by a gas-tight connection, the external pipes with the housing and the pipe bottoms; applying an electrically insulating coating onto inside surfaces of the external pipes; sliding the internal pipes, including the p-doped and n-doped thermoelectric elements, and the external rings into the external pipes; shrinking the external pipes and fitting the external pipes into the internal pipes; and connecting, by a gas-tight connection, the external rings with the internal pipes.

As noted above, in accordance with the present disclosure, external pipes are connected in a gas-tight manner at first with a housing of the thermal electric generator and with pipe bottoms. Thereafter, an electrically insulating coating is applied to the inside surface of the external pipes. Following this, internal pipes with p-doped and n-doped thermoelectric elements on external rings are slid into the external pipes. Thereafter, the external pipes are fitted onto the internal pipes by shrinking, and finally the external rings are connected with the external pipes in a gas-tight manner. In this process sequence, the production or method steps with the highest process temperature occur first. The thermoelectric materials and solders of the thermoelectric modules are subjected to a very low temperature load or none at all in the subsequent process steps.

In accordance with an embodiment of the method in accordance with the present disclosure, the external pipes are connected with the housing by soldering in a vacuum or a through-type furnace by nickel-base soldering at temperatures in the range of approximately 1080° C.

The external pipes are hydraulically fitted by shrinking by applying a working pressure, according to an embodiment of the present disclosure.

In order to avoid a deformation of the housing and the pipe bottoms in hydraulic fitting by shrinking, for example, the housing and the pipe bottoms are externally supported in a mechanical or hydraulic way.

In accordance with another embodiment of a method in accordance with the present disclosure for producing a thermoelectric generator that can be used in an exhaust system of a motor vehicle, the housing is prefabricated at first. Thereafter, the internal modules are prefabricated. The internal modules include external pipes, internal pipes with p-doped and n-doped thermoelectric elements, external rings, functional intermediate layers and pipe bottoms. This previously assembled internal module is welded into the housing in a subsequent process step. An advantage of this embodiment lies in the use of a soldering method with a low input of heat. The prefabricated thermoelectric modules can then be welded directly.

In accordance with another embodiment of a method according to the present disclosure, the housing is produced by soldering or by laser welding. The welding of the internal module into the housing occurs for example, by pulsed laser welding.

In order to ensure that the external pipes are welded together with the pipe bottom, the laser respectively performs a rotation larger than 360°, according to another embodiment of the method in accordance with the present disclosure. The rotation may, for example, be between 365° and 380°. In this way the initial and end zones of the welding will overlap.

Other aspects of the present disclosure will become apparent from the following descriptions when considered in conjunction with the accompanying drawings.

### BRIEF DESCRIPTION OF THE DRAWINGS

FIGS. 1 to 5 show a schematic illustration of a sequence of the individual process steps, according to an embodiment of the method in accordance with the present disclosure.

FIGS. 6 to 8 show a schematic illustration of the sequence of the process steps according to another embodiment of the method in accordance with the present disclosure.

### DETAILED DESCRIPTION

Terms such as top, bottom, left, right, front, and rear relate to the exemplary illustrations chosen in the drawings and, for example, relate to the position of the thermoelectric generators and its components. These terms shall not be understood in any limiting way, meaning that these reference terms can change due to various working positions or mirror-symmetrical configurations.

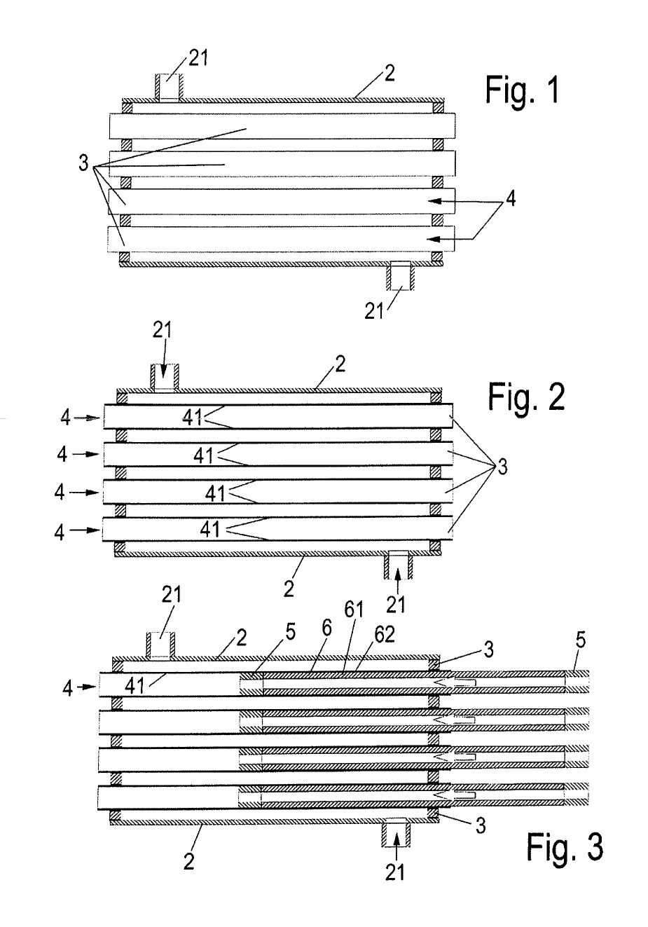

FIGS. 1 to 5 schematically show a sequence of an embodiment of a method, in accordance with the present disclosure, for producing a thermoelectric generator 1 which, for example, is configured to be used in an exhaust system of a motor vehicle. The thermoelectric generator 1 includes a housing 2 in which several thermoelectric modules 7 are arranged. The thermoelectric modules 7 include external pipes 4, internal pipes 6, p-doped and n-doped thermoelectric materials or elements 61, 62 and external rings 5, with the individual thermoelectric modules 7 being separated from one another on a face side by pipe bottoms 3.

As is shown in FIG. 1, the external pipes 4, which may include small thin-walled special steel pipes with an edge thickness of, for example, between 0.1 and 0.3 mm, are connected in a gas-tight and water-proof manner in a first process step with the housing 2 and on a face side, with the pipe bottoms 3 which terminate the housing 2. This connection may occur in a soldering process in a vacuum or through-type furnace, or continuous furnace, by nickel-base solders at temperatures in the range of approximately 1080° C.

The external pipes 4 are coated in a subsequent process step on their inside with an electric insulation 41, as is shown in FIG. 2.

In a further process step, the internal pipes 6, which are provided with p-doped and n-doped thermoelectric materials or elements 61, 62 and external rings 5 arranged at the ends, are slid into the external pipes 4. The coating of the internal pipes 6 with the thermoelectric p-doped and n-doped elements 61, 62 and the introduction of the external rings 5 at the face ends of the internal pipes 6 occur in a separate process step. The introduction of the thus produced internal pipes 6 into the external pipes 4 is shown in FIG. 3.

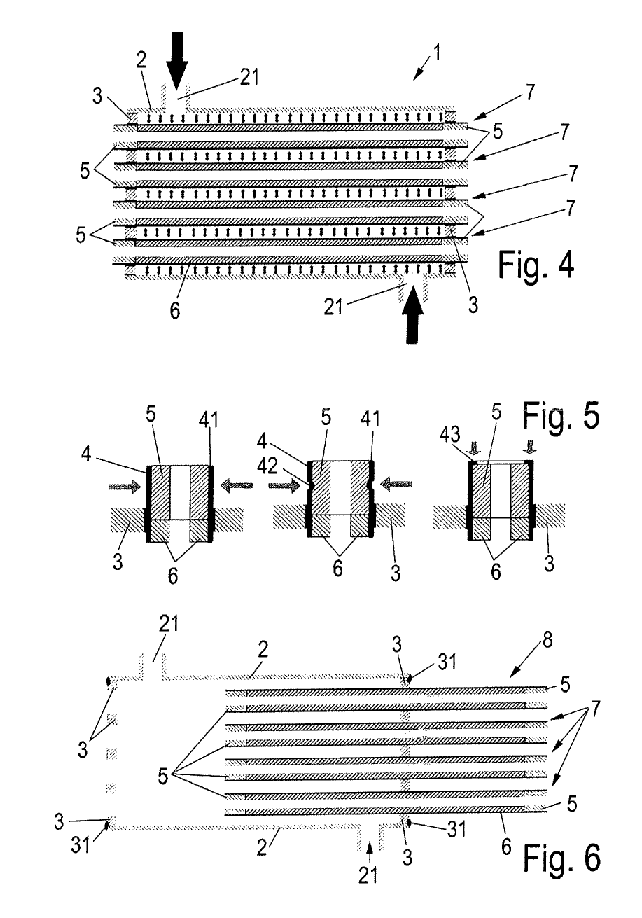

The external pipes 4 are hydraulically fitted by shrinking in a subsequent process step onto the internal pipes 6 by application of a working pressure, as shown in FIG. 4.

For this purpose, a suitable active medium (see dark arrows in FIG. 4) is introduced in an embodiment according to the present disclosure via the connection pieces 21 in a space between the external pipes 4 and the housing wall 2. The introduced working pressure may, for example, be in a range of between 200 and 350 bars.

In order to prevent a deformation of the housing 2 or the pipe bottoms 3 as a result of this introduced working pressure, the housing 2 and the pipe bottoms 3 are mechanically supported, according to an embodiment of the present disclosure, by an apparatus enclosing the housing 2 and the pipe bottoms 3.

In accordance with an embodiment of the present disclosure, the housing 2 and the pipe bottoms 3 are subjected from the outside with an at least equally high pressure. In this case, the thermoelectric modules 7 need to be sealed on their face sides in order to prevent the penetration of the active medium exerting the working pressure into a gap between the external ring 5 and the respective external pipe 4. In order to prevent this, it is within the scope of the present disclosure to use O-rings of sufficient hardness, which, as a result of their hardness, cannot be pressed into the gap between the external ring 5 and the external pipe 4. The gap between the external pipe 4 and the inserted internal pipe 6 must be dimensioned in such a way that plastic deformation of the external pipes 4 can occur as a result of the fitting by shrinking. It is within the scope of the present disclosure to use compressible intermediate layers or compressible thermoelectric materials. In this case, it is within the scope of the present disclosure to omit the gap between the external pipe 4 and the external ring 5.

In a further process step shown in FIG. 5, there is a material connection, or bonding, between the external rings 5 and the external pipes 4 which enclose the same in order to protect the thermoelectric materials 61, 62 introduced in the internal pipes 6 from the penetration of components of the exhaust gas or an occurring exhaust gas condensate. When using thermoelectric materials 61, 62 which may not be subjected to oxygen atmosphere, it needs to be ensured further that the contact of the thermoelectric materials 61, 62 with the oxygen of the ambient air is prevented over the entire period of production.

In accordance with an embodiment of the present disclosure, the external rings 5 are finally mechanically pressed together with the external pipes 4, as shown at 42 and 43 in FIG. 5. Notice must be taken that the electric insulation 41 on the inside of the external pipes 4 is not destroyed. In the event of mechanical pressing of the external rings 5 with the external pipes 4, it may, within the scope of the present disclosure, be provided that a material connection between the external pipes 4 and the outside rings 5 is omitted.

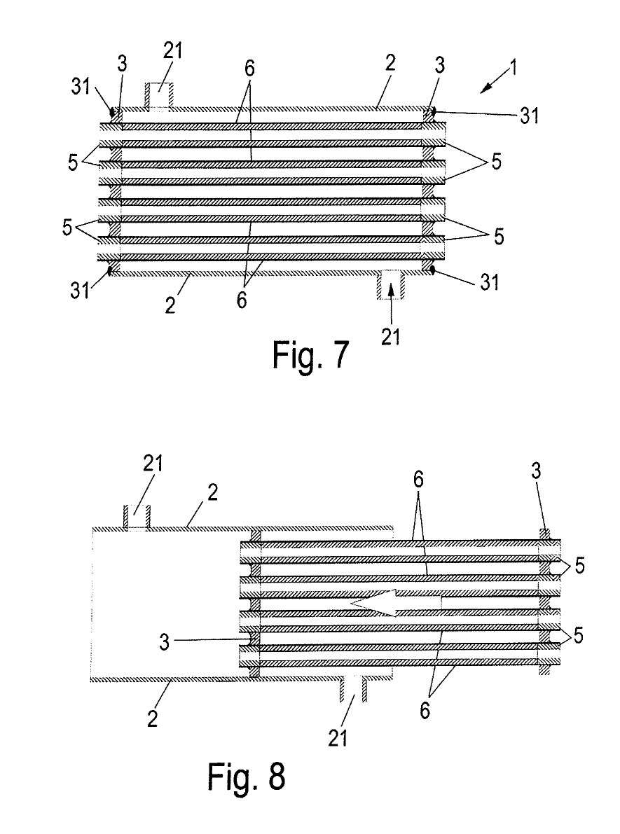

Another method for producing a thermoelectric generator 1, in accordance with the present disclosure, which can be used in an exhaust system of a motor vehicle is discussed below by reference to FIGS. 6 to 8. In this method, the tubular thermoelectric modules, which include the external pipes 4, the internal pipes 6, external rings 5, thermoelectric elements 61, 62 and various functional intermediate layers, are prefabricated at first by a laser welding process, for example, without any additional material, and thereafter welded into a prefabricated housing 2. The housing 2 may be produced in a soldering process or, for example, by laser welding, as shown, or example, at 31 in FIGS. 6 and 7.

The welding on of the prefabricated thermoelectric modules 8 may, for example, occur with a pulsed laser, because this kind of laser system enables short high-energy pulses at high pulse output. It is ensured by using such laser systems, on the one hand, that the input of heat into the thermoelectric modules 8 is very low and the thermoelectric materials 61, 62 and the intermediate layers are not damaged thermally. On the other hand, small welding zones can be realized with such welding processes, with which the external pipes 4, which have a wall thickness of 0.1 to 0.3 mm according to an embodiment of the present disclosure as already described above, can be welded together in a controlled manner without risking welding through the thin-walled external pipes 4. In the case of suitable welding parameters, the maximum temperature on the inside of the external pipes 4 is less than 250° C.

In accordance with an embodiment of the present disclosure, the laser performs a rotation of more than 360° when welding the external pipe 4 with the pipe bottom 3 in order to achieve an overlap of the initial and end zone of the welding. The laser may, according to the present disclosure, perform a rotation of 365° to 380°.

In accordance with another embodiment of the present disclosure, the pipe bottoms 3 can be welded together with the thermoelectric modules 8 in a first step and thereafter be introduced into the housing 2 jointly, as shown in FIG. 8. In this case, the pipe bottoms 3 need to be welded together with the housing 2 by a welding method with low heat input, for example, by laser welding, and optionally, within the scope of the present disclosure, with a pulsed laser.

Although the present disclosure has been described and illustrated in detail, it is to be clearly understood that this is done by way of illustration and example only and is not to be taken by way of limitation. The scope of the present disclosure is to be limited only by the terms of the appended claims.

We claim:

1. A method for producing a thermoelectric generator configured to be used in an exhaust system of a motor vehicle, the thermoelectric generator including a plurality of tubular thermoelectric modules arranged in a housing and including external pipes, internal pipes, p-doped and n-doped thermoelectric elements, and external rings the thermoelectric modules being separated from one another on a face side by pipe bottoms, the method steps comprising:
connecting, by a gas-tight connection, the external pipes with the housing and the pipe bottoms;
applying an electrically insulating coating onto inside surfaces of the external pipes;
sliding the internal pipes, including the p-doped and n-doped thermoelectric elements, and the external rings into the external pipes;
shrinking the external pipes and fitting the external pipes into the internal pipes; and
connecting, by a gas-tight connection, the external rims with the internal pipes.

2. The method according to claim 1, wherein the external pipes are connected with the housing by soldering in a vacuum or a through-type furnace by nickel-base soldering at temperatures in the range of approx. 1080° C.

3. The method according to claim 1, wherein the external pipes fitted hydraulically by shrinking by being subjected to a working pressure.

4. The method according to claim 3, wherein the working pressure lies is in the range of 200 to 350 bars.

5. The method according to claim 3, wherein the housing and the pipe bottoms are supported externally in a mechanical or hydraulic manner in order to prevent deformation of the housing and the pipe bottoms during the hydraulic fitting by shrinking.

6. The method according to claim 1, wherein the connecting of the external rings with the external pipes in a gas-tight manner includes a material connection of the external rings with the external pipes.

7. The method according to claim 1, wherein the connecting of the external rings with the external pipes in a gas-tight manner includes a mechanically pressing together of the external rings with the external pipes.

8. A method for producing a thermoelectric generator configured to be used in an exhaust system of a motor vehicle, the thermoelectric generator including a plurality of tubular thermoelectric modules arranged in a housing and including external pipes, internal pipes, p-doped and n-doped thermoelectric elements, and external rings, the thermoelectric modules being separated from one another on a face side by pipe bottoms, the method stew; comprising:
prefabricating the housing;
prefabricating a tubular internal module including the external pipes, the internal pipes with the p-doped and n-doped thermoelectric elements, the external rings, intermediate layers, and the pipe bottoms; and
welding the internal module into the housing.

9. The method according to claim 8, wherein the prefabricating of the housing is produced by soldering or laser welding.

10. The method according to claim 8, wherein during the prefabricating of the housing the pipe bottoms are connected with the housing.

11. The method according to claim 8, wherein during the prefabricating of the tabular internal module the pipe bottoms are connected with the external pipes.

12. The method according to claim 8, wherein the welding of the internal module into the housing occurs by pulsed laser welding.
